(19) United States
(12) Patent Application Publication
(10) Pub. No.: US 2022/0199631 A1
(43) Pub. Date: Jun. 23, 2022

(54) FERROELECTRIC SEMICONDUCTING FLOATING GATE FIELD-EFFECT TRANSISTOR

(71) Applicant: Advanced Nanoscale Devices, Colorado Springs, CO (US)

(72) Inventors: Carlos A. Paz de Araujo, Colorado Springs, CO (US); Jolanta B. Celinska, Colorado Springs, CO (US); Christopher R. McWilliams, Colorado Springs, CO (US); Jason E. Nobles, Colorado Springs, CO (US)

(73) Assignee: Advanced Nanoscale Devices, Colorado Springs, CO (US)

(21) Appl. No.: 17/558,158

(22) Filed: Dec. 21, 2021

Related U.S. Application Data
(60) Provisional application No. 63/129,389, filed on Dec. 22, 2020.

(51) Int. Cl. H01L 27/1159; H01L 29/51; H01L 29/78

(52) U.S. Cl. CPC H01L 27/1159; H01L 29/78391; H01L 29/516

(57) ABSTRACT

Non-volatile memory devices utilizing polarizable ferroelectric-semiconductor materials as the floating gate in floating-gate field-effect metal oxide transistors are described. Such materials can be annealed at temperatures less than 450° C., and fields below about 250 kV/cm can be used for changing polarization of the ferroelectric semiconductor materials, leading to devices capable of high endurance (>10¹⁰ cycles).

### CROSS-REFERENCE TO RELATED APPLICATIONS

The present application claims the benefit of U.S. Provisional Patent Application No. 63/129,389 for “Ferroelectric Semiconductor Floating Gate Field-Effect Transistor”, which was filed on 22 Dec. 2020, the entire content of which Patent Application is hereby specifically incorporated by reference herein for all that it discloses and teaches.

### BACKGROUND

Flash memory, is a nonvolatile semiconductor memory that is widely used for storage and retrieval of data in consumer devices, enterprise systems and industrial applications. Non-volatile memory retains data for an extended period of time, regardless of whether a flash-equipped device is powered on or off. Flash memory is a form of EEPROM (electrically erasable programmable read-only memory), which uses modern Integrated Circuit voltages for erasure and reprogramming.

Each memory cell in a flash memory resembles a metal-oxide-semiconductor field-effect transistor (MOSFET) having two gates. The upper gate is generally a metal electrode [control gate (CG)], which is similar to the gate in other MOS transistors. The second, lower gate, is electrically insulated by oxide layers, generally silicon dioxide (SiO₂), above and below from both the CG and the semiconductor material (channel) of the MOSFET, and is therefore a floating gate (FG). The FG may be a thin-film layer of conductive or semiconducting material interposed between the CG and the MOSFET channel, typically, polysilicon, doped or undoped. The current flowing between the source and drain of the MOSFET is now controlled by the floating gate (FG), since charge traps formed in the FG, may be filled with electrons tunneling through the oxide layer between the FG and the MOSFET channel, or emptied, depending on the voltage applied to the CG, thereby giving rise to the non-volatile behavior of the device. The electric field created by these charges drops across the FG and into the surface of the MOSFET channel region. The threshold voltage is the voltage applied to the gate stack (CG, FG and insulating layers) at which the transistor can change conduction as a function of the charges in the FG. If the FG has trapped electrons, a higher voltage must be applied to the CG to make the channel conductive. The presence of a logical “0” or “1” on the MOSFET is sensed by determining whether there is current flowing through the transistor when an intermediate voltage between the threshold voltages is applied to the CG. If the channel conducts at this intermediate voltage, the FG must be uncharged (reading), since if it were charged, conduction would not occur because the intermediate voltage is less than the required voltage, and a logical “1” is stored in the gate. If the channel does not conduct at the intermediate voltage, the FG must have a charge, and a logical “0” is stored in the gate.

Ferroelectric materials exhibit a spontaneous electrical polarization in the absence of an external electric field. Such polarization is due to ion displacement in the crystal, and is reversible in the presence of an electric field having opposite polarity. Thus, polarization switching can be triggered by an external electric field, and such materials can have two electrically controllable nonvolatile states. Ferroelectric materials are also dielectric materials having a large band gap. If a ferroelectric insulator is employed as a gate insulator in a metal-oxide semiconductor field-effect transistor (MOSFET), the channel conductance (source-to-drain) may be used to detect the polarization state so that the data reading operation is non-destructive. Thus, if the voltage applied to the CG is greater than the coercive voltage of the ferroelectric material, the polarization is directed toward the p-substrate (in an n/p/n semiconductor) and electrons will accumulate in the channel. The MOSFET is then in the on-state (“1”). If the CG voltage is less than the negative of the coercive voltage, the polarization reverses and electrons in the p-substrate are depleted giving rise to the device being in the off-state (“0”). To reduce chemical reactions and intermixing between the ferroelectric material and the transistor material, an insulator layer is often used to separate the materials.

However, ferroelectric field-effect transistors have short retention time, because of the depolarization field and the gate leakage current, which can cause charge accumulation at the ferroelectric insulator/semiconductor interface and lead to threshold voltage drift and destruction of the memory state. The depolarization field is the result of the potential drop across the interfacial dielectric and the band bending of the semiconductor, which leads to charge trapping at the ferroelectric insulator/semiconductor interface.

### SUMMARY

In accordance with the purposes of the present invention, as embodied and broadly described herein, an embodiment of the floating gate field-effect transistor for non-volatile memory, hereof, includes: a field-effect transistor body including a source electrode, a drain electrode, a body electrode, a semiconductor material, and an upper surface, at least a portion of the upper surface being disposed between the source electrode and the drain electrode; a polarizable ferroelectric semiconductor layer having a first surface and a second surface; a first layer of electrical insulating material disposed between and in contact with the upper surface of the transistor body between the source and drain electrodes thereof and the first surface of the ferroelectric semiconductor layer, for providing electrical insulation between the transistor body and the ferroelectric semiconductor layer; a gate electrode; and a second layer of electrical insulating material disposed between and in contact with the second surface of the ferroelectric semiconductor layer and the gate electrode; whereby the ferroelectric semiconductor layer is completely electrically isolated from the transistor body and from the gate electrode.

In another embodiment of the present invention and in accordance with its objects and purposes, as embodied and broadly described herein, an embodiment of the ferroelectric semiconductor, hereof, includes Bi₄Ti₃O₁₂ doped with greater than about 0.5 atomic mass percent, and less than or equal to about 20 atomic mass percent of BiₓO_{y}, where 1≤x≤2, and 1≤y≤3.

In yet another embodiment of the present invention and in accordance with its objects and purposes, as embodied and broadly described herein, an embodiment of the ferroelectric semiconductor, hereof, includes Bi₄Ti₃O₁₂+xBi₂O₃+yNb₂O₃, where x is greater than about 0.5 atomic mass percent, and less than or equal to about 20 atomic mass percent, and y is less than about 1 atomic mass percent.

Benefits and advantages of the present invention include, but are not limited to, providing a floating gate field-effect transistor for a flash memory employing polarizable ferroelectric-semiconductor materials as the floating gate, whereby the annealing step in the fabrication process can occur at temperatures lower than 450° C., control gate fields below about 250 kV/cm can be used for switching polarization of the ferroelectric semiconductor materials for bit storage and erasure, and devices capable of high endurance (>10¹⁰ cycles) are achievable. Insulating ferroelectric materials cannot be satisfactorily annealed below 450° C., which is a requirement for MOSFETs having channel lengths less than 90 nm.

### BRIEF DESCRIPTION OF THE DRAWINGS

The accompanying drawings, which are incorporated in and form a part of the specification, illustrate the embodiments of the present invention and, together with the description, serve to explain the principles of the invention. In the drawings:

FIG. 1 is a schematic representation of a PRIOR ART floating gate metal oxide field-effect transistor (FGMOSFET) commonly used as a flash field-effect transistor (FET).

FIG. 2 is a schematic representation of an embodiment of a ferroelectric semiconductor field-effect transistor (FeSFET) of the present invention, where the ferroelectric semiconductor floating gate is not connected to the gate electrode.

FIG. 3 is a hypothetical graph of the thickness of the ferroelectric semiconductor as a function of the annealing temperature, illustrating that for fast diffusants, thinner ferroelectric semiconductor materials 50 nm) can be annealed at lower temperatures.

FIG. 4 is a hypothetical graph of the capacitance (F/μm²) as a function of voltage for the apparatus shown in FIG. 2 hereof for Bi₄Ti₃O₁₂ doped with less than 15% by atomic mass of BiₓO_{y}, where 1≤x≤2, and 1≤y≤3 (BiO or Bi₂O₃, or mixtures thereof), illustrating the effect of the polarizability of the ferroelectric semiconductor.

### DETAILED DESCRIPTION

Briefly, embodiments of the present invention employ polarizable ferroelectric-semiconductor materials as the floating gate in non-volatile flash memory devices such as floating-gate field-effect metal oxide transistors. With proper fabrication, such materials can be annealed at temperatures lower than 450° C. Further, fields below about 250 kV/cm can be used for switching polarization of the ferroelectric semiconductor materials, leading to devices capable of high endurance (>10¹⁰ cycles).

Although ferroelectric semiconductors are known, for example, indium selenide (α-In₂Se₃), ferroelectric materials are not naturally semiconducting, for example, Bi₄Ti₃O₁₂, BaTiO₃, and aurivillius ferroelectric materials, but may be rendered semiconducting by doping with electron donors.

Present field-effect transistor non-volatile memory devices typically employ polysilicon or doped polysilicon as materials for the floating gate, electrically insulated from the control gate and from the transistor semiconductor materials by SiO₂. Also as mentioned above, insulating ferroelectric materials are employed as gate insulators in metal-oxide semiconductor field-effect transistors. However, use of this combination can lead to charge trapping at the ferroelectric insulator/semiconductor (transistor body) interface. Further, to reduce chemical reactions and intermixing between the ferroelectric material and the transistor material, an insulator layer is often used to separate the materials. An additional insulator is often used to stop leakage between the control gate electrode and the ferroelectric insulator material as well.

In what follows, the terms set forth will be used as defined. The term “floating gate” shall mean a thin-film or layer of conductive or semiconducting material, which is not connected to an electrode. The term “ferroelectric material” shall mean an insulating material or dielectric having spontaneous polarization with a wide or large band gap. The term “ferroelectric field-effect transistor (FeFET)” shall mean an FET having a ferroelectric material as the FET gate insulator. The term “ferroelectric semiconductor material (FeS)” shall mean a material having semiconductor properties, that is, having spontaneous polarization, a smaller band gap when compared to dielectrics (insulators), and a conductivity that sharply increases with increasing temperature. A “ferroelectric semiconductor field-effect transistor (FeSFET)” shall mean an FET having a ferroelectric semiconductor as a floating gate, which is not connected to an electrode.

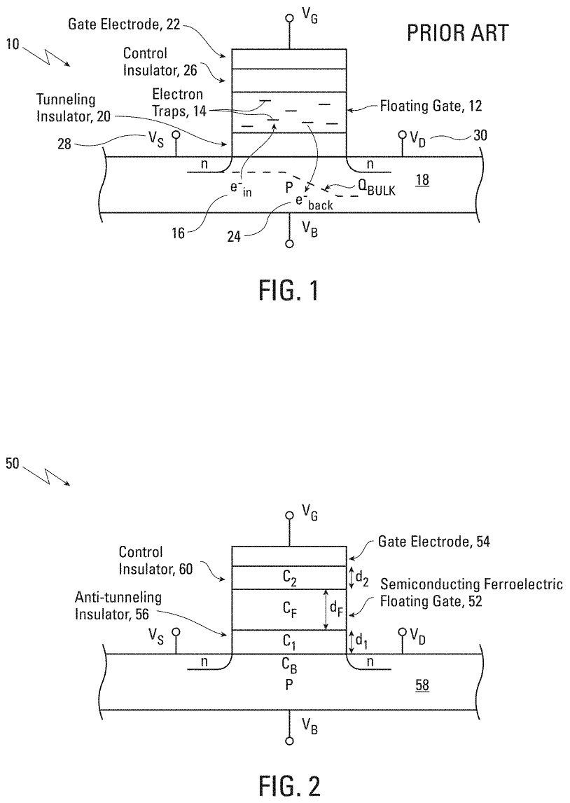

A. FIG. 1 is a schematic representation of PRIOR ART floating gate metal oxide field-effect transistor (FGMOSFET), 10, commonly used as a flash FET. Floating gate, 12, is often fabricated from polysilicon material, which as stated above has poor electrical conductivity. Non-volatile behavior of flash FET 10 derives from the filling or emptying electron traps, 14, in floating gate 12 from the tunneling of electrons, 16, in semiconductor (transistor body), 18, through thin tunneling layer, 20, which may include an oxide. The polarity of V_{G}, the voltage applied to gate electrode, 22, controls the filling or trapping (V_{G}>0) or emptying (V_{G}<0) of traps 14, electrons, 24, being pushed back into semiconductor (transistor body) 18 through tunneling insulator 20 by gate voltage V_{G}. Floating gate 12 is insulated from gate electrode 22 by control insulator, 26. Reading of the stored state may be accomplished by sensing the source-to-drain electrodes (V_{S}, 28, is the source electrode, and Vo, 30, is the drain electrode) current, which derives from the state of Q_{FG} as follows:

Q_{FG}˜±Q_{bulk}˜±Q_{Depletion}, (1)

if no channel has been established in the semiconductor, and

Q_{FG}˜±Q_{bulk}˜±Q_{Depletion}+Q_{channel}, (2)

if a channel has been established.

Now,

Q_{FG}=∫₀^{τ}i_{prog}dt, (3)

where τ is the programming time, and i_{prog} is the tunneling current through lower oxide thin film insulator 20 of FET 10, and

$$Δ {V}_{T} = \pm ( \frac{{Q}_{F G}}{{C}_{o x}} ) = \pm ( \frac{{\int }_{0}^{τ} {i}_{prog} dt}{{C}_{o x}} ) , \qquad ( 4 )$$

where ΔV_{T} is the change in threshold voltage for the two charge states, and Cₒₓ is the capacitance of the non-ferroelectric material floating gate field-effect transistor. The threshold voltage is the voltage applied between gate electrode 22 and source electrode 28, usually grounded of MOSFET 10 that is needed to turn the device on. Semiconductor material 18, shown as a source/body/drain, S/B/D, silicon n/p/n MOSFET transistor element, can also be a p/n/p MOSFET transistor.

Existing non-volatile memories have several limitations. First, V_{G} needs to be large (˜8V) for tunneling to occur through the tunneling oxide layer between the floating gate and the semiconductor in order to create the charge traps in the floating gate. Moreover, the tunneling current is slow (˜8-10 μs/bit), and damages tunneling oxide layer 20, thereby limiting endurance of the flash memory. Such devices also exhibit fatigue in 10⁴-10⁵ programming (read/write) cycles, since charges may be permanently trapped in the polysilicon floating gate. As memories are made smaller, scaling below about 32×32 nm² permits only about 35 electrons to be trapped in the floating gate, causing retention failures. This is a major drawback because Q_{FG} is small and cannot affect significant changes in Q_{Bulk} beyond the normal values of a basic transistor, which limits the cell size to above 32 nm.

B. As mentioned above, ferroelectric field-effect transistors (FeFET) have a ferroelectric material as the FET gate insulator. Many of these devices do not have additional electrical insulation between the gate electrode and the ferroelectric insulator, but others use an insulating buffer layer to reduce leakage current. Typical ferroelectric materials being insulating (σ˜0), require a high V_{G}, which is not useful for low-voltage, highly scaled FETs (<65 nm).

Technologies for <90 nm field-effect transistors require T_{Annealing≤}450° C. Therefore, whether buffer layers are present, ferroelectric materials cannot be used for <90 nm technologies, because forming an insulating ferroelectric film requires temperatures 500° C., which temperatures are destructive to semiconductors at the lithographic nodes. An exception to this limitation arose with the recent discovery of ultrathin HfO₂ (having thicknesses 15 nm; typically, 10 nm), which when doped with Si, Zr, Cd, Sb, and other materials, and using TiN (titanium nitride) as a top electrode to stabilize the underlying material, becomes a metastable ferroelectric material that can be annealed at T˜400° C. However, fields≥2 MV/cm are needed to program the memory state, and the metastable aspect of this material means that it has low endurance and poor repeatability. With the requirement of such high fields, and difficulty of using buffer layers, which increase V_{G}, no commercial devices are currently available.

Thus, no stable floating gate ferroelectric field-effect transistor has been achieved before the introduction of floating gate field-effect transistors using ferroelectric semiconductor materials, as set forth in embodiments of the present invention.

C.1. Reference will now be made in detail to the present embodiments of the invention, examples of which are illustrated in the accompanying drawings. In the Figures, similar structure will be identified using identical reference characters. It will be understood that the FIGURES are presented for the purpose of describing particular embodiments of the invention and are not intended to limit the invention thereto. Turning now to FIG. 2, shown is a schematic representation of an embodiment of ferroelectric semiconductor field-effect transistor (FeSFET), 50, where ferroelectric semiconductor floating gate, 52, is not connected to gate electrode, 54. Insulating material, 56, between and in contact with ferroelectric semiconducting material 52 and the upper surface of semiconductor material, 58, between source (V_{S}) and drain (V_{D}) electrodes, now an anti-tunneling material for electrons, include Hf₁₋ₓZrₓO₂, where 0≤x≤1, as examples of effective materials for such purpose. Control or gate electrode insulator, 60, provides electrical insulation between and in contact with ferroelectric semiconducting material 52 and gate electrode 54 which is connected to applied voltage, V_{G}. Effective insulating materials include Hf₁₋ₓZrₓO₂, where 0≤x≤1. Again, semiconductor material 58, shown as a S/B/N silicon n/p/n MOSFET transistor element, can also be a p/n/p MOSFET transistor.

As briefly mentioned above, the ferroelectric semiconductors effective for use in embodiments of the present invention have the following properties: (1) an annealing temperature 500° C., preferably, 450° C.; (2) low leakage by tunneling through insulating materials employed to electrically insulate the ferroelectric semiconductor from both the metallic control gate and from the semiconducting layer of the transistor, which lengthens the memory retention; and (3) polarization switching at low voltages.

For low-temperature processing, ferroelectric semiconductors can be fabricated by adding fast diffusants or fluxors (materials having higher crystallization velocities than the ferroelectric component), such as BiO, Bi₂O₃ (there are many polymorphs of bismuth oxide), BaO, SiOₓ, where x≤2, and the like, thereby forming a solid solution of the fluxors (solute) in polycrystalline ferroelectric materials (solvent). As these fluxors are hole dopants, polarization retention is improved by counter doping with electron dopants, such as Nb, which increases the net APᵣ-Qₙ, and decreases the leakage current beyond the substantial decrease in leakage current resulting from the electrical isolation of the ferroelectric semiconductor. Thus, addition of fluxors reduces the annealing temperature of the Bi₄Ti₃O₁₂ or BaTiO₃ ferroelectric materials, as examples, while excessive doping (≥0.5 atomic weight or mass percent) with these materials generates the semiconducting properties thereof, with counter doping with n-type atoms decreasing the leakage current and increasing the net APᵣ-Qₙ, where A is the area of the floating gate.

Polarizable ferroelectric semiconducting material 52 includes Bi₄Ti₃O₁₂ doped with greater than about 0.5 atomic mass percent, and less than or equal to about 20 atomic mass percent of BiₓO_{y}, where 1≤x≤2, and 1≤y≤3 (BiO or Bi₂O₃, or mixtures thereof). Although 15% doping of Bi₄Ti₃O₁₂ with Bi₂O₃ without counter doping has been found to have too much leakage current at the voltages employed, such films anneal at 400° C. However, doping levels between about 0.5 and about 20 atomic weight percent of Bi₂O₃ have been found to provide annealing temperatures below about 400° C., and with counter doping with less than about 1 atomic weight percent of transition metals and rare earth dopants, such as Nb, La, Ta, Zr, Dy, Sm, and Cr, as examples, will be useful in generating high polarizations with acceptable carrier concentrations in the Bi₄Ti₃O₁₂ ferroelectric semiconductors (low leakage currents). However, at sufficiently high concentrations of these materials, free carriers cease to be generated.

Ferroelectric semiconducting layer 52 may include Bi₄Ti₃O₁₂+xBi₂O₃+yNb₂O₃, where x is greater than about 0.5 atomic mass percent, and less than or equal to about 20 atomic mass percent, and y is less than about 1 atomic mass percent.

C.2. It can be shown from the Einstein-Smoluchowski diffusion relationship for Brownian motion (See, e.g., “Diffusion In Solids” by H. Mehrer, Springer, 2010) that

d_{F}=N_{eff}(\sqrt{tₐₙₙₑₐₗ})e^{-E}^{_{A}}^{/2kT}, where (4)

d_{F} is the thickness of the ferroelectric semiconductor, N_{eff} is a constant related to the effective number of diffusion lengths, tₐₙₙₑₐₗ is the annealing time for a fast diffusant or solute in the ferroelectric solvent, where many particle jumps can occur, and E_{A} is the activation energy to form the desired properties.

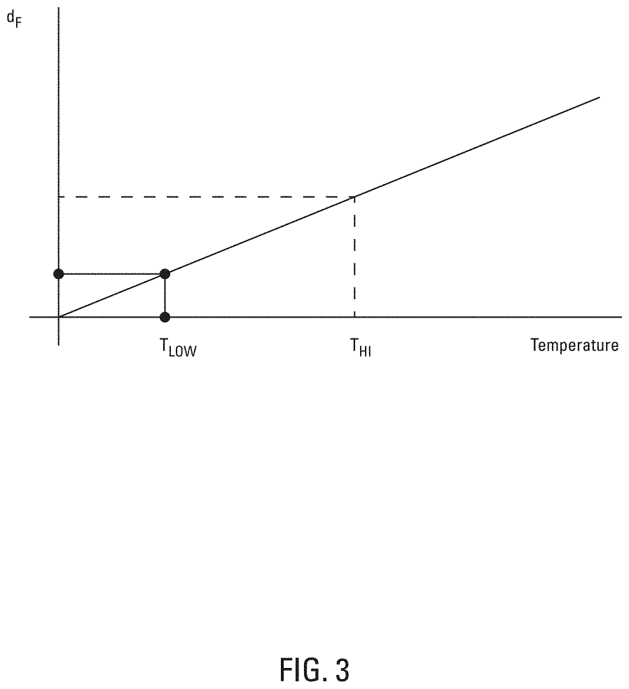

FIG. 3 is a hypothetical graph showing the thickness of the ferroelectric semiconductor, d_{F}, as a function of the annealing temperature from Equ. 4, illustrating that for fast diffusants, thinner ferroelectric semiconductor materials (≤50 nm) can be annealed at lower temperatures, ≤T_{LOW}. As will be discussed below, d_{F} can also be obtained by geometric scaling, as well as being derived as a function of temperature, dopant species, and annealing time.

C.3. For a ferroelectric semiconducting floating gate,

$${J}_{total} = 0 = σ E + \frac{dD}{dt} , \qquad ( 5 )$$

after t=0, where

D=ϵ₀E+P≈P, (6)

and P is the spontaneous polarization of the ferroelectric semiconductor.

### Then,

Q_{FG}˜±(PᵣA−Qₙ), where (7)

$${Q}_{n} = \frac{σ}{μ} ,$$

the remnant polarization, Pᵣ˜Pₛₚₒₙₜ, σ and μ are the ferroelectric conductivity and mobility, respectively, and A is the area of the floating gate, from which

ΔV_{T}=±(Q_{FG}−Qₙ/C_{stack}), (8)

where ΔV_{T} is the change in threshold voltage for the two polarization states, and C_{stack} is the capacitance of the entire ferroelectric semiconductor floating gate, including the ferroelectric semiconductor and the control and anti-tunneling insulators.

Now,

$$\begin{matrix}\frac{1}{{C}_{s t a c k}} = \frac{1}{{C}_{1}} + \frac{1}{{C}_{F}} + \frac{1}{{C}_{2}} , or {C}_{s t a c k} = \frac{{C}_{F} {C}_{2}}{1 + \frac{{C}_{2}}{{C}_{1}} + \frac{{C}_{F}}{{C}_{1}}} & ( 9 ) \\ where {C}_{1} = \frac{{ϵ}_{1}}{{d}_{1}} {ɛ}_{0} A , {C}_{F} = \frac{{ϵ}_{F}}{{d}_{F}} {ɛ}_{0} A , and {C}_{2} = \frac{{ϵ}_{2}}{{d}_{2}} {ϵ}_{0} A & \end{matrix}$$

are the capacitances of anti-tunneling insulator 56, ferroelectric semiconductor 52, and control insulator 60, ϵ₁, ϵ_{F}, and ϵ₂ are the relative permittivity's of insulator 56, ferroelectric semiconductor 52, and insulator 60, respectively, ϵ₀ is the permittivity of free space, and A is the area of gate electrode 54. The thickness of insulator 56 is d₁, that of ferroelectric semiconductor 52 is d_{F}, and that of control insulator 60 is d₂. Stack optimization occurs when

C_{F}˜C_{stack}˜C_{Bulk}, (10)

where C_{Bulk} is the depletion capacitance of the transistor body (silicon),

$${C}_{B u l k} = \frac{{ϵ}_{s i}}{{W}_{B} ( V )} {ϵ}_{0} A ,$$

where ϵₛᵢ is the relative permittivity of silicon, and W_{B}(V) is the depletion distance in the silicon below insulating material 58 and under gate electrode 54 including W_{D} and W_{S}, for the source and drain. This condition permits the major portion of the voltage applied at gate electrode 54 to be applied to ferroelectric semiconductor 52, which then leads to lower device voltage requirements, and faster polarization switching. For a MOSFET, at zero applied voltage

$${W}_{B}^{0} ( V ) = \sqrt{\frac{2 {ϵ}_{0} {ϵ}_{s i} {ψ}_{s} ( V )}{q {N}_{A}}} , \qquad$$

where ψₛ(v) is the surface potential of the silicon body, which depends on the direction of the polarization, N_{A} is the body doping for a p-type MOSFET, and q is the electron carrier charge. W_{B}(V) is at its maximum when maximum depletion occurs at the onset of the channel. Optimization is attained by choosing ϵ₁, ϵ₂, ϵ_{F}, d₁, d₂, and d_{F}, further yielding:

d_{F}>>d₁ and d₂, and ϵ_{F}>>ϵ₁ and ϵ₂. (11)

Of note is that σ≠0, which has the following consequences. First, ferroelectric semiconductors are fatigue free (>10¹⁰ read/write cycles), and switching time 13 ns/bit for a 180 nm technology node. Additionally, from Equation 7, the threshold voltage is low (≤1.2 V), because Pᵣ′<Pᵣ, and the area can be scaled to 3-5 nm. Further, to be certain that the ferroelectric semiconductor is truly a floating gate, electron tunneling therein is limited to zero.

Having described the general details of embodiments of the present invention, the following EXAMPLES provide additional details.

### Example 1

C.4 Stack Optimization:

As stated above, stack optimization occurs when C_{F}˜C_{stack}˜C_{bulk}, and

$${C}_{stack} = \frac{{C}_{F} {C}_{2}}{1 + \frac{{C}_{2}}{{C}_{1}} + \frac{{C}_{F}}{{C}_{1}}} .$$

### Now,

$${C}_{1} = \frac{{ϵ}_{1}}{{d}_{1}} {ϵ}_{0} A ,$$

d₁ is commonly determined by fabrication requirements, and by choosing the insulating materials, ϵ₁ is also fixed (about 20 for HfO₂); therefore, C₁ is fixed. Therefore,

$${C}_{F} \approx \frac{{C}_{F} {C}_{2}}{1 + \frac{{C}_{2}}{{C}_{1}} + \frac{{C}_{F}}{{C}_{1}}} ≡ {γ}_{1} {C}_{F} , and {γ}_{1} = \frac{{C}_{2}}{1 + \frac{{C}_{2}}{{C}_{1}} + \frac{{C}_{F}}{{C}_{1}}} = 1 ,$$

to provide the desired result. Then,

$${C}_{F} = \frac{{C}_{2}}{1 + \frac{{C}_{2}}{{C}_{1}} + \frac{{C}_{F}}{{C}_{1}}} ,$$

from which

$$\begin{matrix}\frac{{C}_{1}}{{C}_{F}} < \frac{{C}_{F}}{{C}_{2}} & \\ {C}_{F} < \sqrt{{C}_{1} {C}_{2}} . & ( 12 ) \\ Since {C}_{F} = \frac{{ϵ}_{F}}{{d}_{F}} {ϵ}_{0} A , {C}_{1} = \frac{{ϵ}_{1}}{{d}_{1}} {ϵ}_{0} A , and {C}_{2} = \frac{{ϵ}_{2}}{{d}_{2}} {ϵ}_{0} A , & \\ {( \frac{{ϵ}_{F}}{{d}_{F}} )}^{2} < \frac{{ϵ}_{1}}{{d}_{1}} \frac{{ϵ}_{2}}{{d}_{2}} , and {d}_{F} > {ϵ}_{F} \sqrt{\frac{{d}_{1}}{{ϵ}_{1}} \frac{{d}_{2}}{{ϵ}_{2}}} . & ( 13 )\end{matrix}$$

Further, since C_{bulk}˜C_{F}<\sqrt{C₁C₂},

$$\frac{{ϵ}_{s i}}{{W}_{B} ( V )} < \sqrt{\frac{{ϵ}_{1}}{{d}_{1}} \frac{{ϵ}_{2}}{{d}_{2}}} , and {W}_{B} ( V ) > {ϵ}_{S i} \sqrt{\frac{{d}_{1}}{{ϵ}_{1}} \frac{{d}_{2}}{{ϵ}_{2}}} , \qquad ( 14 )$$

which links the body doping of the silicon channel and the stack, independent of the ferroelectric semiconductor.

Finally, the stack is designed such that d₂ is a function of d₁, and d_{F}>>d₁+d₂. Returning to Equ. 9,

$${C}_{s t a c k} = \frac{{C}_{F} {C}_{2}}{1 + \frac{{C}_{2}}{{C}_{1}} + \frac{{C}_{F}}{{C}_{1}}} \approx \frac{{C}_{F} {C}_{2}}{\frac{{C}_{2}}{{C}_{1}} + \frac{{C}_{F}}{{C}_{1}}} = {λ}_{2} {C}_{F} ,$$

and defining

$${λ}_{1} = \frac{{ϵ}_{2} {d}_{1}}{{ϵ}_{1} {d}_{2}} ,$$

d₂ is adjusted to render λ₂=1. Then.

$$\frac{{ϵ}_{2}}{{d}_{2}} {ϵ}_{0} A = {λ}_{1} + \frac{{C}_{F}}{{C}_{1}} = {λ}_{1} + \frac{{ϵ}_{F} {d}_{1}}{{ϵ}_{1} {d}_{F}} \cdot {ϵ}_{F} = 1 + \frac{\vert {P}_{r} \vert}{{ϵ}_{0} {E}_{C}} \approx \frac{\vert {P}_{r} \vert}{{ϵ}_{0} {E}_{C}} ,$$

where E_{c} is the coercive field, and Pᵣ is the remnant polarization. Thus,

$${d}_{2} = \frac{{ϵ}_{2} {ϵ}_{0} A}{{λ}_{1} + \frac{\vert {P}_{r} \vert {d}_{1}}{{E}_{C} {ϵ}_{0} {ϵ}_{1} {d}_{F}}} = \frac{{ɛ}_{2} {ϵ}_{0} A}{\frac{{ϵ}_{2} {d}_{1}}{{ϵ}_{1} {d}_{2}} + \frac{\vert {P}_{r} \vert {d}_{1}}{{E}_{C} {ϵ}_{0} {ϵ}_{1} {d}_{F}}} , \qquad ( 15 )$$

and for a given ϵ₁, ϵ₂, d₁, d_{F}, and Pᵣ, d₂ is adjusted such that C_{stack}=C_{F}, and

$${λ}_{1} = \frac{{C}_{2}}{{C}_{1}} \geq 1$$

by optimizing C₂.

### Example 2

C.5 Thin films (≤30 nm) of doped Bi₄Ti₃O₁₂ were prepared by atomic layer deposition on a 5 nm film of HfO₂ and covered with a 5 nm film of HfO₂ before a step of rapid thermal annealing at 400° C. for 1 min. under nitrogen. Suspensions of Bi₂O₃ and Bi₄Ti₃O₁₂ in methanol, octane or xylene, as solvents, were spun onto a rotating substrate at a chosen rpm and the solvent evaporated in a furnace. Polarization hysteresis curves were generated using 1 MHz triangular waves at 1, 2, 3, 4, and 5 V.

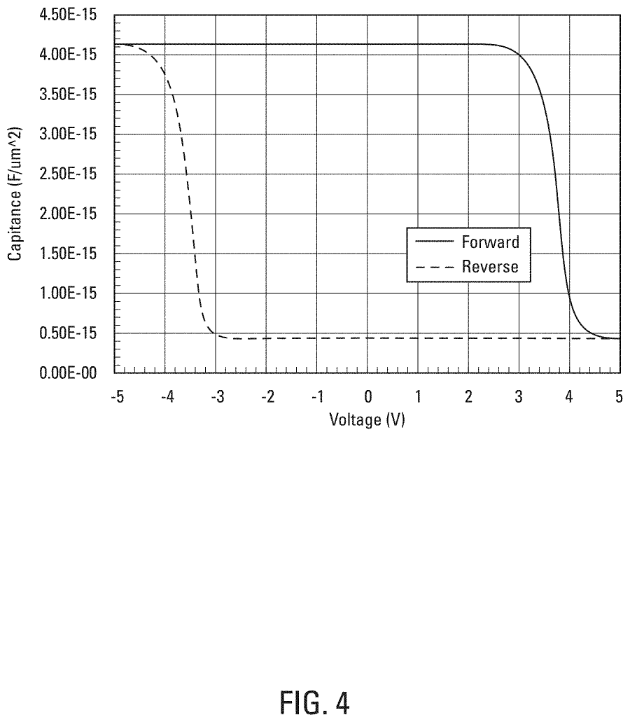

FIG. 4 is a hypothetical graph of the capacitance (F/μm²) as a function of voltage for the apparatus shown in FIG. 2 hereof for Bi₄Ti₃O₁₂ doped with less than 15% by atomic mass of BiₓO_{y}, where 1≤x≤2, and 1≤y≤3 (BiO or Bi₂O₃, or mixtures thereof), illustrating the effect of the polarizability of the ferroelectric semiconductor.

The foregoing description of the invention has been presented for purposes of illustration and description and is not intended to be exhaustive or to limit the invention to the precise form disclosed, and obviously many modifications and variations are possible in light of the above teaching. The embodiments were chosen and described in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

What is claimed is:

1. A floating gate field-effect transistor for non-volatile memory, comprising:
a field-effect transistor body comprising a source electrode, a drain electrode, a body electrode, a semiconductor material, and an upper surface, at least a portion of the upper surface being disposed between the source electrode and the drain electrode;
a polarizable ferroelectric semiconductor layer having a first surface and a second surface;
a first layer of electrical insulating material disposed between and in contact with the upper surface of said transistor body between the source and drain electrodes thereof and the first surface of said ferroelectric semiconductor layer, for providing electrical insulation between said transistor body and said ferroelectric semiconductor layer;
a gate electrode; and
a second layer of electrical insulating material disposed between and in contact with the second surface of said ferroelectric semiconductor layer and said gate electrode;
whereby said ferroelectric semiconductor layer is completely electrically isolated from said transistor body and from said gate electrode.

2. The floating gate field-effect transistor of claim 1, wherein said field-effect transistor comprises a metal oxide semiconductor field-effect transistor.

3. The floating gate field-effect transistor of claim 1, wherein the charge carriers of said transistor body comprise electrons or holes.

4. The floating gate field-effect transistor of claim 3, wherein said first layer of electrical insulating material is an anti-tunneling material for electrons.

5. The floating gate field-effect transistor of claim 4, wherein said first layer of electrical insulating material comprises Hf₁₋ₓZrₓO₂, where 0≤x≤1, and said second layer of electrical insulating material comprises Hf₁₋ₓZrₓO₂, where 0≤x≤1.

6. The floating gate field-effect transistor of claim 5, wherein said first layer of electrical insulating material comprises dielectric HfO₂, and said second layer of electrical insulating material comprises dielectric HfO₂.

7. The floating gate field-effect transistor of claim 1, wherein said ferroelectric semiconducting layer comprises Bi₄Ti₃O₁₂ doped with greater than about 0.5 atomic mass percent, and less than or equal to about 20 atomic mass percent of BiₓO_{y}, where 1≤x≤2, and 1≤y≤3.

8. The floating gate field-effect transistor of claim 7, wherein said ferroelectric semiconducting layer comprises: Bi₄Ti₃O₁₂ doped with greater than about 0.5 atomic mass percent, and less than or equal to about 20 atomic mass percent of BiₓO_{y}, where 1≤x≤2, and 1≤y≤3, and less than about 1 atomic mass of elements chosen from Nb, La, Ta, Zr, Dy, Sm, and Cr, and mixtures thereof.

9. The floating gate field-effect transistor of claim 8, wherein said ferroelectric semiconducting layer comprises: Bi₄Ti₃O₁₂+xBi₂O₃+yNb₂O₃, where x is greater than about 0.5 atomic mass percent, and less than or equal to about 20 atomic mass percent, and y is less than about 1 atomic mass percent.

10. The floating gate field-effect transistor of claim 1, wherein
$${C}_{B} ∼ \frac{{C}_{F} {C}_{2}}{1 + \frac{{C}_{2}}{{C}_{1}} + \frac{{C}_{F}}{{C}_{1}}} ,$$
d_{F}>>d₁ and d₂, and ϵ_{F}>>ϵ₁ and ϵ₂, where C_{F}, C₁, and C₂ are the capacitances of said layer of ferroelectric semiconductor, said first layer of electrical insulating material, and said second layer of electrical insulating material, respectively, C_{B} is the capacitance of the field-effect transistor body, d_{F}, d₁, and d₂ are the thicknesses of said layer of ferroelectric semiconductor, said first layer of electrical insulating material, and said second layer of electrical insulating material, respectively, and ϵ_{F}, ϵ₁, and ϵ₂ are the permittivities of said layer of ferroelectric semiconductor, said first layer of electrical insulating material, and said second layer of electrical insulating material, respectively.

11. A ferroelectric semiconductor, comprising Bi₄Ti₃O₁₂ doped with greater than about 0.5 atomic mass percent, and less than or equal to about 20 atomic mass percent of BiₓO_{y}, where 1≤x≤2, and 1≤y≤3.

12. The ferroelectric semiconductor of claim 11, further comprising less than about 1 atomic mass of elements chosen from Nb, La, Ta, Zr, Dy, Sm, and Cr, and mixtures thereof.

13. The ferroelectric semiconductor of claim 11, wherein said ferroelectric semiconductor is annealed at less than about 450° C.

14. The ferroelectric semiconductor of claim 11, wherein polarization of said ferroelectric semiconductor is reversed at a voltage less than about 250 kV/cm.

15. A ferroelectric semiconducting layer, comprising: Bi₄Ti₃O₁₂+xBi₂O₃+yNb₂O₃, where x is greater than about 0.5 atomic mass percent, and less than or equal to about 20 atomic mass percent, and y is less than about 1 atomic mass percent.

16. The ferroelectric semiconductor of claim 15, wherein said ferroelectric semiconductor is annealed at less than about 450° C.

17. The ferroelectric semiconductor of claim 15, wherein polarization of said ferroelectric semiconductor is reversed at a voltage less than about 250 kV/cm.
